(19) United States
(12) Patent Application Publication
(10) Pub. No.: US 2009/0320895 A1
(43) Pub. Date: Dec. 31, 2009

(54) SOLAR CELL MODULE

(75) Inventors: Toshio Yagiura, Osaka (JP); Naoya Sotani, Osaka (JP)

Correspondence Address: MOTS LAW, PLLC, 1629 K STREET N.W., SUITE 602, WASHINGTON, DC, 20006-1635, US

(73) Assignee: Sanyo Electric Co., Ltd., Moriguchi (JP)

(21) Appl. No.: 12/439,247

(22) PCT Filed: Aug. 28, 2007
(86) PCT No.: PCT/JP2007/066648

§ 371 Date: Mar. 30, 2009

(30) Foreign Application Priority Data
Aug. 31, 2006 (JP) 2006-236146

(51) Int. Cl. H01L 31/042

(52) U.S. Cl. 136/244

(57) ABSTRACT

In a thin film solar cell module, a photovoltaic layer and a sealing layer 16 are sequentially disposed on a transparent substrate 11, the photovoltaic layer formed by connecting in series multiple photovoltaic elements each formed by sequentially stacking a transparent conductive film 12, photovoltaic conversion layers, and a rear surface electrode 15. Meanwhile, in a region where the rear surface electrodes 15 of the photovoltaic elements adjacent to each other are electrically separated, a metal film 18 is provided on a surface of the transparent conductive film 12 at a side of the sealing layer 16.

### TECHNICAL FIELD

The present invention relates to a solar cell module in which a photovoltaic layer and a sealing layer are sequentially disposed on a transparent substrate, the photovoltaic layer formed by connecting in series multiple photovoltaic elements each formed by sequentially stacking a first electrode, a photovoltaic conversion layer, and a second electrode.

### BACKGROUND ART

In recent years, thin film solar cell modules that use a small amount of raw materials have been developed intensively in order to achieve cost reduction and higher efficiency of solar cells at the same time. An example of a cross-sectional view of such a thin film solar cell module is shown in FIG. 1 and FIG. 2.

In general, a photovoltaic element of a thin film solar cell module 50 is formed by sequentially stacking a transparent conductive film 52, a photovoltaic conversion layer 53, and a rear surface electrode 54 on an impermeable transparent substrate 51 such as glass while patterning them by laser irradiation from the side of the substrate. Moreover, the thin film solar cell module is formed by bonding a rear surface film 56 such as PET (polyethylene terephthalate) onto the photovoltaic element by using a sealing layer 55 such as EVA (ethylene vinyl acetate) (see Patent Document 1, for example).

Here, the sealing layer 55 has functions as an adhesive as well as a buffer between the rear surface film 56 and the photovoltaic element, and the rear surface film 56 has a function to prevent moisture penetration from outside.

### Patent Document 1: JP-A 8-204217

### DISCLOSURE OF THE INVENTION

### Problem to be Solved by the Invention

In general, solar cell modules are often used outdoors. For this reason, solar cell modules need to have sufficient weather resistance for maintaining stable and high power generation under severe climate conditions. In particular, thin film solar cell modules are likely to have their thin film materials deteriorated easily with moisture penetration from outside and so forth. Therefore, a thin film solar cell module has to have a structure that can maintain a stable and high power generation even if moisture penetrates.

However, depending on the material and the structure of the rear surface film, such as PET, used for preventing moisture penetration from outside, some of the rear surface films cannot prevent moisture penetration completely. In such a case, if the moisture having penetrated the sealing layer 55 reaches the transparent conductive film 52, the transparent conductive film 53 easily deteriorates. As a consequence, a problem arises that the thin film solar cell module cannot maintain a stable and high power generation.

Accordingly, in view of the above-mentioned problem, an object of the present invention is to provide a thin film solar cell module which is capable of maintaining a stable and high power generation even if moisture penetrates.

### Means for Solving the Problem

A first aspect of the present invention provides a solar cell module in which a photovoltaic layer that is formed by connecting in series multiple photovoltaic elements each formed by sequentially stacking a first electrode, a photovoltaic conversion layer, and a second electrode, and a sealing layer are sequentially disposed on a transparent substrate. Here, in a region electrically separating the second electrodes of the photovoltaic elements adjacent to each other, a metal film is provided on a surface of the first electrode at the side of the sealing layer.

According to the solar cell module of the first aspect, the provision of the metal film makes it possible to maintain electrical connection of a junction between the first electrode and the second electrode favorably even when the first electrode of this part is deteriorated by moisture penetration. As a result, the solar cell module can maintain a stable and high power generation even if the moisture penetrates.

In the solar cell module according to the first aspect, the metal film may be provided at a portion where the first electrode of one of the photovoltaic elements is connected to the second electrode of the photovoltaic element adjacent thereto.

According to this solar cell module, it is possible to reduce resistance of the junction with the connection between the metal film and the first electrode.

A second aspect of the present invention provides a solar cell module in which a photovoltaic layer that is formed by connecting in series multiple photovoltaic elements each formed by sequentially stacking a first electrode, a photovoltaic conversion layer, and a second electrode, and a sealing layer are sequentially disposed on a transparent substrate. Here, in a region electrically separating the second electrodes of the photovoltaic elements adjacent to each other, a metal film is provided on a surface of the transparent substrate at the side of the sealing layer.

According to the solar cell module of the second aspect, even when the first electrode of this part is deteriorated by moisture penetration, electric resistance will be not reduced because the metal film maintains electric conduction. For this reason, the solar cell module can maintain a stable and high power generation.

Meanwhile, in the solar cell module according to the second aspect, the metal film may be provided on the transparent substrate in a portion extending from the surface facing the sealing layer so as to contact the sealing layer.

According to this solar cell module, the first electrode is likely to be prevented from deteriorating because the first electrode does not exist in the region of separation.

Meanwhile, in the solar cell modules according to the first and second aspects, the metal film preferably has a high melting point equal to or above 1700° C.

This solar cell module has the melting point equal to or higher than that of the normal first electrode. Accordingly, this solar cell module is advantageous not being melted by a laser or the like.

Meanwhile, in the solar cell modules according to the first and second aspect, the first electrode may contain ZnO. Since ZnO has a highly water-soluble property, the effect is particularly more likely to be achieved by applying the present invention.

### EFFECT OF THE INVENTION

According to the present invention, it is possible to provide a thin film solar cell module which is capable of maintaining a stable and high power generation even if moisture penetrates.

### BRIEF DESCRIPTION OF THE DRAWINGS

FIG. 1 is a cross-sectional view showing a configuration of a conventional thin film solar cell module.

FIG. 2 is an enlarged cross-sectional view showing the configuration of the conventional thin film solar cell module.

FIG. 3 is an enlarged cross-sectional view showing a configuration of a thin film solar cell module according to an embodiment and a first example.

FIG. 4 is an enlarged cross-sectional view showing a configuration of a thin film solar cell module according to the embodiment and a second example.

FIG. 5 is an enlarged cross-sectional view showing a configuration of a thin film solar cell module according to the embodiment and a third example.

FIG. 6 is an enlarged cross-sectional view showing a configuration of a thin film solar cell module according to the embodiment and a fourth example.

FIG. 7 is a graph showing results of moisture resistance tests of a thin film solar cell module according to an example of the invention and a thin film solar cell module according to a conventional example.

### BEST MODES FOR CARRYING OUT THE INVENTION

Next, an embodiment of the present invention will be described by using the drawings. In the following description of the drawings, identical or similar parts are denoted by identical or similar reference symbols. It is to be noted, however, that the drawings are merely schematic and proportions of respective dimensions and the like are different from actual ones. Therefore, concrete dimensions and the like are supposed to be determined in consideration of the following description. Moreover, it is needless to say that the drawings may contain factors regarding relations and proportions of the dimensions which are different among the drawings.

(Solar Cell Module)

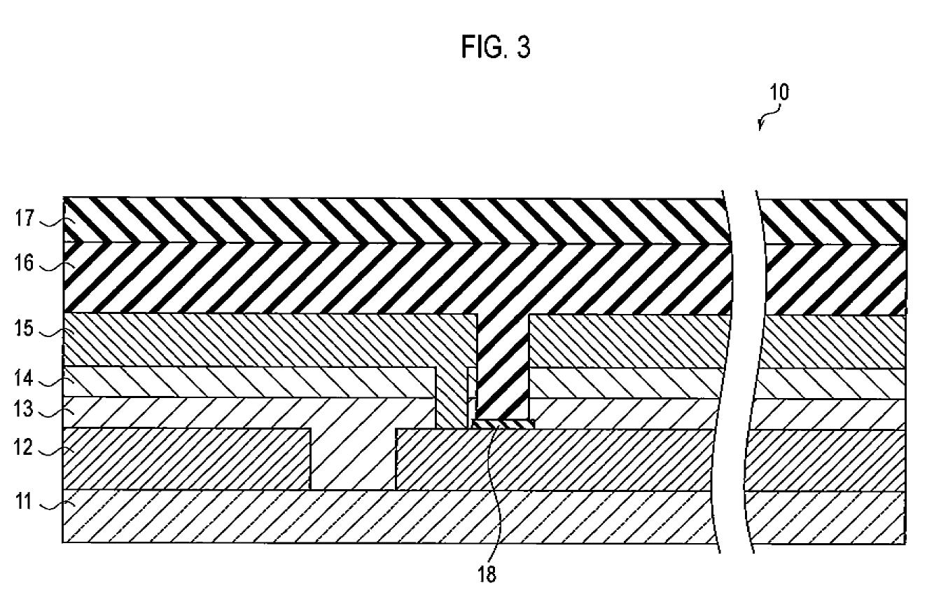

As shown in FIG. 3, a thin film solar cell module 10 according to this embodiment includes multiple photovoltaic elements, a boding layer 16, and a rear surface film 17, which are sequentially disposed on a transparent substrate 11. Each of the multiple photovoltaic elements is formed by sequentially stacking a transparent conductive layer 12, photovoltaic conversion layers 13 and 14, and a rear surface electrode 15. Moreover, in FIG. 3, multiple photovoltaic elements, a sealing layer 16, and a rear surface film 17 are sequentially disposed on the transparent substrate 11 at a side of a rear surface which is opposite to a light entering side.

The transparent substrate 11 is a single substrate of the solar cell module. The multiple photovoltaic elements are formed on the transparent substrate 11 at the side of the rear surface which is opposite to the light entering side. The transparent substrate 11 is made of a light transmissive member such as glass.

The transparent conductive film 12 (a first electrode) is formed into a strip shape in a plan view of the transparent substrate 11. The transparent conductive film 12 is made of a single or multiple metal oxides, which form a stacked body, selected from among a group of the metal oxides obtained by doping any of Sn, Sb, F, and Al into any of ZnO, In₂O₃, SnO₂, CdO, TiO₂, CdIn₂O₄, Cd₂SnO₄, and Zn₂SnO₄. Here, ZnO is suitable for the transparent conductive film material as having high optical transmission, low resistance, and plasticity while being inexpensive. ZnO is used as the transparent conductive film according to this embodiment.

The photovoltaic conversion layers 13 and 14 are formed into strip shapes on the transparent conductive film 12. The photovoltaic conversion layers 13 and 14 are made of crystalline or amorphous silicon semiconductor. The photovoltaic conversion layers 13 and 14 according to this embodiment are made of amorphous silicon semiconductor and microcrystalline silicon semiconductor, respectively. In this specification, the term “microcrystalline” is supposed to mean not only a completely crystalline state but also a state containing partially amorphous state.

Here, the photovoltaic conversion layer 13 according to this embodiment is formed by sequentially stacking p-i-n type amorphous silicon semiconductor. The photovoltaic conversion layer 14 is formed by sequentially stacking p-i-n type microcrystalline silicon semiconductor. Such a tandem-type solar cell module employing amorphous silicon and microcrystalline silicon has the structure formed by stacking two types of semiconductor each having a different optical absorption wavelength. Accordingly, the solar spectrum can be effectively utilized.

The rear surface electrode 15 (a second electrode) is formed into a strip shape on the photovoltaic conversion layers 13 and 14. The rear surface electrode 15 is made of a conductive member such as Ag.

In this way, the photovoltaic element is formed by sequentially stacking the transparent conductive film 12, the photovoltaic conversion layers 13 and 14, and the rear surface electrode 15 on the transparent substrate 11.

The rear surface film 17 is disposed on the sealing layer 16. The rear surface film 17 is made of a resin film such as PET, PEN, ETFE, PVDF, PCTFE, PVF or PC. Alternatively, the rear surface film 17 may have a structure in which resin films sandwich a metal foil, or be made of metal (a steel plate) such as SUS or Galvalume. The rear surface film 17 has a function to prevent penetration of moisture from outside as much as possible.

The rear surface film 17 is attached onto the photovoltaic elements by use of the sealing layer 16. The sealing layer 16 is made of resin such as EVA, EEA, PVB, silicone, urethane, acryl or epoxy. The sealing layer 16 has functions as an adhesive and a buffer between the rear surface film 17 and the photovoltaic elements.

In order to simplify the explanation below, one located on the left side out of the two photovoltaic elements will be described as a first photovoltaic element while one located on the right side will be described as a second photovoltaic element in FIG. 3.

The transparent conductive films 12 of the first photovoltaic element and the second photovoltaic element are electrically separated from each other. The rear surface electrodes 15 of the first photovoltaic element and the second photovoltaic element are electrically separated from each other. The photovoltaic conversion layers 13 and 14 of the first photovoltaic element and the second photovoltaic element are electrically separated from each other. The rear surface electrode 15 of the first photovoltaic element is electrically connected to the transparent conductive film 12 of the second photovoltaic element via a region obtained by separating the photovoltaic conversion layers 13 and 14. By electrically connecting the first photovoltaic element to the second photovoltaic element in series in this way, an electric current flows in one direction.

Here, in the photovoltaic elements according to this embodiment, a metal film 18 is disposed on a surface of the transparent conductive film 12 at the side of the sealing layer 16 in a region electrically separating the rear surface electrodes 15 of the photovoltaic elements adjacent to each other. Here, in addition to single metal, the term “metal film” also refers to materials such as alloys and resin paste containing metal. Moreover, the metal film 18 preferably has a high melting point equal to or above 1700° C. The examples of metal having such a high melting point may be Cr, Ir, Nb, Pt, Mo, Ta, Th, W, and Zr.

Although the first photovoltaic element and the second photovoltaic element are separately described above, multiple photovoltaic elements having the aforementioned configuration are connected on the transparent substrate 11 in the thin film solar cell module 10 according to this embodiment.

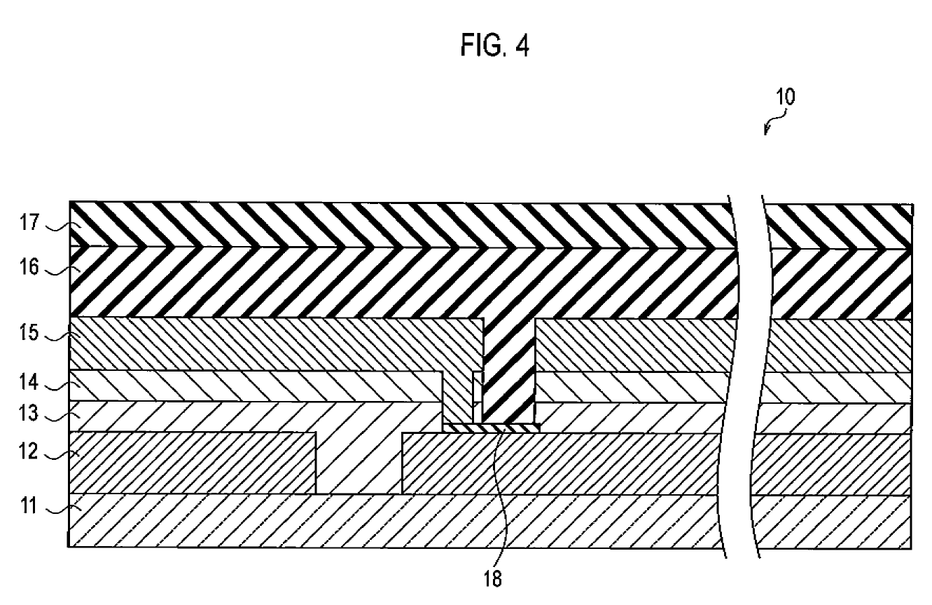

Next, other structures of the solar cell module according to this embodiment will be described by using FIGS. 4 to 7.

In a solar cell module shown in FIG. 4, the metal film 18 is provided to extend from the region where the rear surface electrodes 15 of the photovoltaic elements adjacent to each other are electrically separated to a portion where the rear surface electrode 15 of the photovoltaic element (the first photovoltaic element) is connected to the transparent conductive film 12 of the photovoltaic element (the second photovoltaic element) adjacent to the aforementioned photovoltaic element.

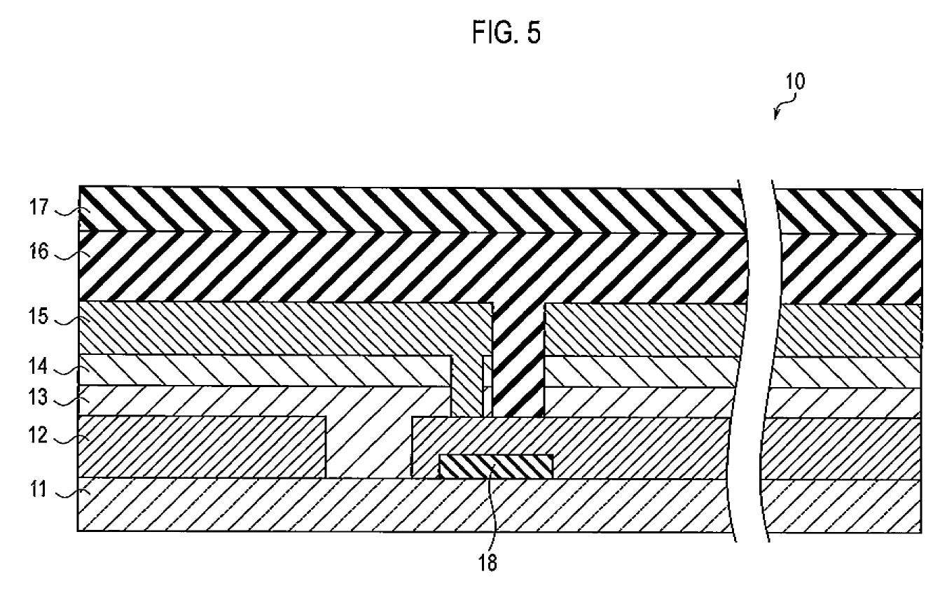

Meanwhile, in a solar cell module shown in FIG. 5, the metal film 18 is provided on a surface of the transparent substrate 11 at the side of the sealing layer 16 in the region where the rear surface electrodes 15 of the photovoltaic elements adjacent to each other are electrically separated.

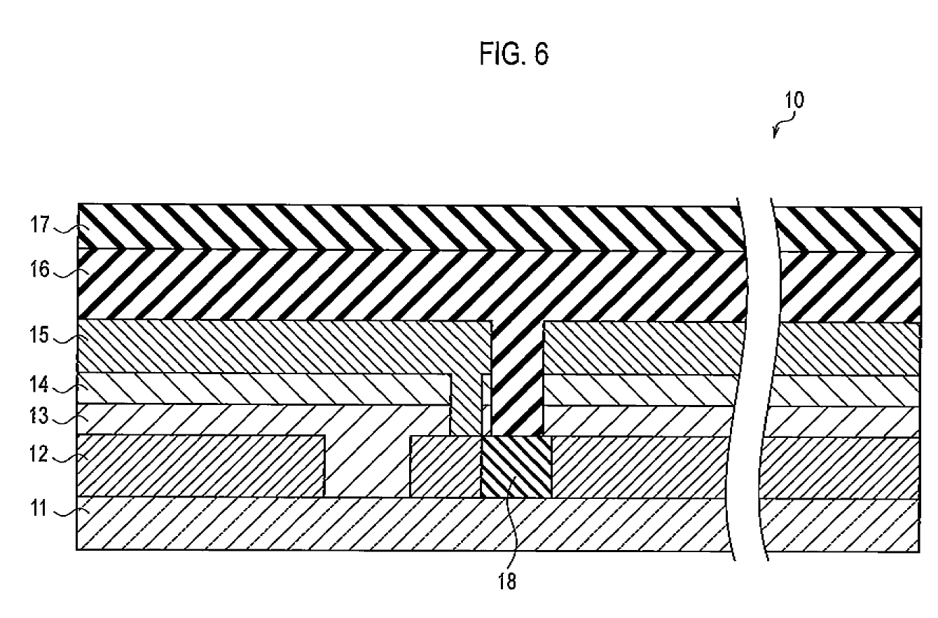

Meanwhile, in a solar cell module shown in FIG. 6, the metal film 18 is provided to extend from the surface of the transparent substrate 11 at the side of the sealing layer 16 so as to contact the sealing layer 16.

(Operation and Effect)

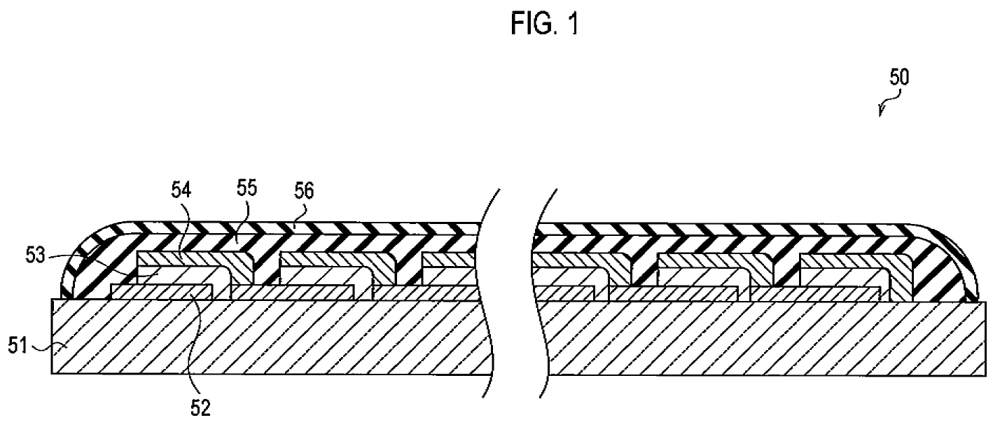

As shown in FIG. 1, in the conventional thin film solar cell module, the rear surfaces 54 are patterned by the layer irradiation from the transparent substrate 51 side for the purpose of improvement on manufacturing efficiency and the like. Therefore, the sealing layer 55 is provided on the transparent conductive film 52.

On the other hand, in the thin film solar cell module according to this embodiment, the metal film 18 is provided on the surface of the transparent conductive film 12 at the side of the sealing layer 16 in the region where the rear surface electrodes 15 of the photovoltaic elements adjacent to each other are electrically separated as shown in FIG. 3. With this configuration, it is possible to maintain a stable and high power generation even if moisture penetrates from outside. To be more precise, the moisture penetrating from the rear surface side of the solar cell module into the rear surface film 17 and the sealing layer 16 is shielded by the metal layer 18 and therefore does not reach the transparent conductive film 12. In this way, the thin film material or the transparent conductive film 12 in particular is prevented from deteriorating due to moisture penetration from outside.

Moreover, in the conventional solar cell module, the rear surface electrode 15 is electrically connected to the transparent conductive film 12 as shown in FIG. 1. In contrast, in the solar cell module according to this embodiment, as shown in FIG. 4, the metal film 18 is provided to extend from the region where the rear surface electrodes 15 of the photovoltaic elements adjacent to each other are electrically separated to the portion where the rear surface electrode 15 of the photovoltaic element (the first photovoltaic element) is connected to the transparent conductive film 12 of the photovoltaic element (the second photovoltaic element) adjacent to the aforementioned photovoltaic element.

Therefore, the rear surface electrode 15 is electrically connected to the transparent conductive film 12 with the metal layer 18 interposed therebetween. For this reason, resistance at a metal junction is reduced and the resistance is further reduced because the transparent conductive film 12 keeps a contact with the meal layer 13 having a larger area.

Meanwhile in the solar cell module according to this embodiment, as shown in FIG. 5, the metal film 18 is provided on the surface of the transparent substrate 11 at the side of the sealing layer 16 in the region where the rear surface electrodes 15 of the photovoltaic elements adjacent to each other are electrically separated.

Accordingly, even if the transparent conductive film 12 is deteriorated by moisture penetration, the electric resistance is not reduced because the metal film 18 achieves electric conduction. Moreover, since the metal film 18 is formed prior to formation of the transparent conductive film 12, the processes thereafter are simplified.

Meanwhile, in the solar cell module according to this embodiment, as shown in FIG. 6, the metal film 18 is provided to extend from the surface of the transparent substrate 11 at the side of the sealing layer 16 so as to contact the sealing layer 16. Therefore, the transparent conductive film 12 is not deteriorated because no transparent conductive film 12 is provided in the region obtained by separating the transparent conductive films 12. Although the vicinity of the transparent conductive film 12 may also be slightly deteriorated by moisture, the metal film 16 achieves higher reliability as having an effect to block the moisture against the transparent conductive films 12 on the right and left thereof.

Meanwhile, the metal film 18 preferably has the high melting point equal to or above 1700° C. This solar cell module has an advantage that the metal film 18 is not melted by a laser or the like at the patterning as having the melting point that is equal to or higher than that of the usual transparent conductive film 12. For this reason, it is possible to pattern the rear surface electrodes 15 reliably.

Meanwhile, when the transparent conductive film 12 is made of ZnO as in the embodiment of the present invention, the transparent conductive film 12 is more likely to be deteriorated easily by moisture as compared to the case where the transparent conductive film 12 is made of other metal oxides. In other words, ZnO is advantageous as the material of the transparent conductive film in terms of optical and electrical characters as well as cost performance as compared to the other metal oxides, but has the property that it is easily deteriorated by moisture.

With these properties taken into consideration, the metal layer 18 is provided in the embodiment of the present invention to prevent the moisture penetration, thereby allowing the use of ZnO which is highly advantageous as the material of the transparent conductive film 12.

### Other Embodiments

Although the present invention has been described above based on the embodiment, it is not to be understood that the description and drawings constituting part of this disclosure limit the scope of this invention. It is obvious to those skilled in the art that various other alternative embodiments, examples, and technical applications are possible from the teachings of this disclosure.

For example, ZnO is used as the transparent conductive film 12 in the above-described embodiment. However, the present invention is not limited to this configuration. It is also possible to use a single or multiple metal oxides, which form a stacked body, selected from among a group of the metal oxides obtained by doping any of Sn, Sb, F, and Al into any of In₂O₃, SnO₂, CdO, TiO₂, CdIn₂O₄, Cd₂SnO₄, and Zn₂SnO₄.

Meanwhile, the above-described embodiment uses the sequentially stacked photovoltaic conversion layers 13 and 14 which respectively are the amorphous silicon semiconductor and the microcrystalline silicon conductor. However, it is also possible to obtain a similar effect by using a single layer or a stacked body of three or more layers of microcrystalline or amorphous silicon semiconductor.

Meanwhile, in the process for separating the rear surface electrodes 15, dry etching may be employed. Alternatively, wet etching and the like may also be employed.

As described above, the present invention naturally includes various other embodiments which are not expressly stated herein. Therefore, the technical scope of the present invention will be solely determined by matters to define the invention pursuant to scope of the appended claims that are reasonable from the above description.

### EXAMPLES

Now, the thin film solar cell module according to the present invention will be more concretely described below with reference to examples. It is to be understood, however, that the present invention will not be limited only to the examples shown below, and that various modifications are possible without changing the scope thereof.

### Example 1

A thin film solar cell module according to Example 1 of the present invention is manufactured as follows.

As shown in FIG. 3, a ZnO electrode 12 having a thickness of 600 nm is formed on a glass substrate 11 having a thickness of 4 mm by means of a sputtering method. Next, a metal film 18 made of Ag is formed into a strip shape with a width of 100 μm and a thickness of 100 nm by using a mask.

Thereafter, the ZnO electrode 12 in a position laterally spaced apart from the metal layer 18 by about 150 μm is irradiated with YAG laser from the ZnO electrode 12 side of the glass substrate 11, and thus is patterned into a strip shape. In this laser separation process, employed is Nd:YAG laser having a wavelength of about 10.6 μm, an energy density of 13 J/cm³, and a pulse frequency of 3 kHz.

Next, an amorphous silicon semiconductor layer 13 and a microcrystalline silicon semiconductor layer 14 are formed by means of a plasma CVD method. To be more precise, the amorphous silicon semiconductor layer 13 is made by means of the plasma CVD method by sequentially forming a p-type amorphous silicon semiconductor layer having a film thickness of 10 nm from mixed gas of SiH₄, CH₄, H₂, and B₂H₆, then an i-type amorphous silicon semiconductor layer having a film thickness of 300 nm from mixed gas of SiH₄ and H₂, and then an n-type amorphous silicon semiconductor layer having a film thickness of 20 nm from mixed gas of SiH₄, H₂, and PH₃. Meanwhile, the microcrystalline silicon semiconductor layer 14 is made by means of the plasma CVD method by sequentially forming a p-type microcrystalline silicon semiconductor layer having a film thickness of 10 nm from mixed gas of SiH₄, H₂, and B₂H₆, then an i-type microcrystalline silicon semiconductor layer having a film thickness of 2000 nm from mixed gas of SiH₄ and H₂, and then an n-type microcrystalline silicon semiconductor layer having a film thickness of 20 nm from mixed gas of SiH₄, H₂, and PH₃. Here, details of various conditions applicable to the plasma CVD method will be shown in Table 1.

TABLE 1
Condition Table for Plasma CVD

| | | Substrate | Gas Flow | Reaction | RF | Thickness |
|---|---|---|---|---|---|---|
| | | Temperature | Rate | Pressure | Power | of Film |
| | Layer | (° C.) | (sccm) | (Pa) | (W) | (nm) |
| a-Si | p layer | 180 | SiH₄: 300 | 106 | 10 | 10 |
| Film | | | CH₄: 300 | | | |
| | | | H₂: 2000 | | | |
| | | | B₂H₆: 3 | | | |
| | i layer | 200 | SiH₄: 300 | 106 | 20 | 300 |
| | | | H₂: 2000 | | | |
| | n layer | 180 | SiH₄: 300 | 133 | 20 | 20 |
| | | | H₂: 2000 | | | |
| | | | PH₃: 5 | | | |
| Microcrys- | p layer | 180 | SiH₄: 10 | 106 | 10 | 10 |
| talline | | | H₂: 2000 | | | |
| Si film | | | B₂H₆: 3 | | | |
| | i layer | 200 | SiH₄: 100 | 133 | 20 | 2000 |
| | | | H₂: 2000 | | | |
| | n layer | 200 | SiH₄: 10 | 133 | 20 | 20 |
| | | | H₂: 2000 | | | |
| | | | PH₃: 5 | | | |

Meanwhile, the amorphous silicon semiconductor layer 13 and the microcrystalline silicon semiconductor layer 14 in a position laterally spaced apart by about 50 μm from the patterned position of the ZnO electrode 12 are irradiated with YAG laser from the ZnO electrode 12 side and thus are patterned into strip shapes. In this laser separation process, employed is Nd:YAG laser having an energy density of 0.7 J/cm³ and a pulse frequency of 3 kHz.

Next, an Ag electrode 15 having a thickness of 200 nm is formed on the microcrystalline silicon semiconductor layer 14 by a sputtering method. The Ag electrode 15 is also formed in the region obtained by removing the amorphous silicon semiconductor layer 13 and the microcrystalline silicon semiconductor layer 14 by patterning.

Meanwhile, The Ag electrode 15 and the microcrystalline silicon semiconductor layer 14 in a position laterally spaced apart by about 50 μm from the patterned positions of the amorphous silicon semiconductor layer 13 and the microcrystalline silicon semiconductor layer 14 are irradiated with YAG laser from their rear surface side, and thus are patterned into strip shapes. In this laser separation process, employed is Nd:YAG laser having an energy density of 0.7 J/cm³ and a pulse frequency of 4 kHz. Further, dry etching with CF₄ is carried out for several tens of seconds. In this way, formed is a submodule in which the multiple photovoltaic elements are connected to each other in series is formed on the glass substrate 11.

Next, external electrodes are provided by use of ultrasonic solder and copper foil leads.

Next, EVA 16 and a PET film 17 are sequentially provided on the photovoltaic elements and are heat-treated at 150° C. for 30 minutes by using a laminating apparatus. In this way, the EVA 16 is cross-linked and stabilized, thereby vacuum-bonding the EVA 16.

Lastly, the thin film solar cell module according the example of the present invention is finished by attaching a terminal box and connecting the external electrodes thereto.

### Example 2

A solar cell module shown in FIG. 4 is fabricated as Example 2 of the present invention. In Example 2, the processes similar to Example 1 are executed except that the metal layer 18 is formed to have a width of 170 μm.

### Example 3

A solar cell module shown in FIG. 5 is fabricated as Example 3 of the present invention. In Example 3, the processes similar to Example 1 are executed except that the metal layer 18 is formed, by the sputtering method using a mask on the glass substrate, to have a width of 200 μm and a thickness of 100 nm and then the ZnO electrode 12 is formed to have a thickness of 600 nm.

### Example 4

A solar cell module shown in FIG. 6 is fabricated as Example 4 of the present invention. In Example 4, after the ZnO electrode 12 is patterned by laser as similar to Example 1, a part of the ZnO electrode 12 in a width of 150 μm is removed similarly by laser in a position laterally spaced apart from the laser-patterned position by 200 μm. The laser conditions at this time are the same as those in the initial patterning process. Next, the metal film 18 made of Ag is formed by using a sputtering method at a portion obtained by removing the ZnO electrode 12 with a mask. In this case, the metal film 18 preferably has a width slightly larger than that of the portion obtained by removing the ZnO electrode 12. Procedures after the process of forming the photovoltaic conversion layer by the plasma CVD method are similar to those in Example 1.

### Conventional Example

A thin film solar cell module according to a conventional example is manufactured as described below.

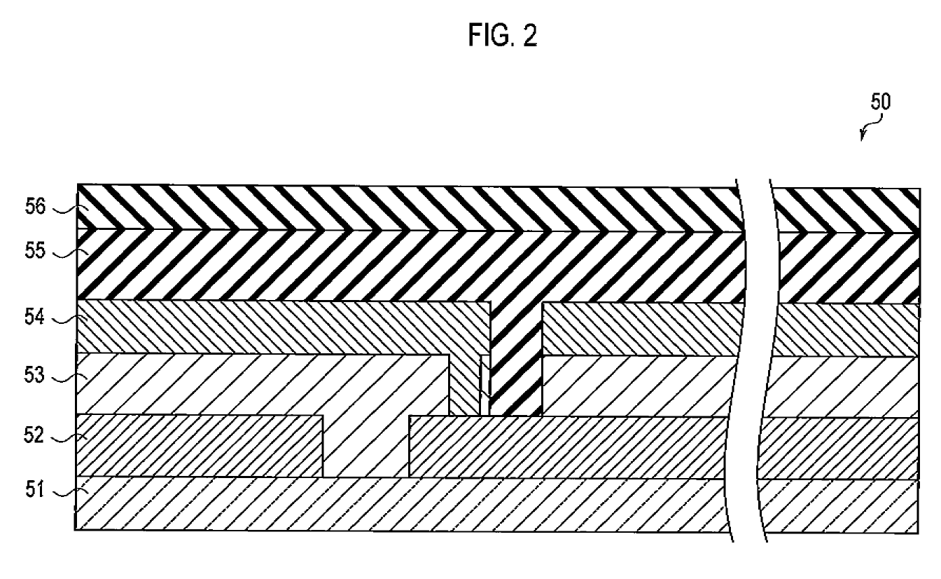

As shown in FIG. 2, A ZnO electrode 52 having a thickness of 600 nm is formed on a glass substrate 51 having a thickness of 4 mm by sputtering. The ZnO electrode 52 is irradiated with YAG laser from the ZnO electrode 52 side of the glass substrate 51, and thus is patterned into a strip shape in order to electrically separate the ZnO electrodes 52. In this laser separation process, employed is Nd:YAG laser having a wavelength of about 1.06 μm, an energy density of 13 J/cm³, and a pulse frequency of 3 kHz.

Next, a microcrystalline silicon semiconductor layer 53 is formed by means of the plasma CVD method. To be more precise, the microcrystalline silicon semiconductor layer 53 is made by means of the plasma CVD method by sequentially forming a p-type microcrystalline silicon semiconductor layer having a film thickness of 10 nm from mixed gas of SiH₄, H₂, and B₂H₆, then an i-type microcrystalline silicon semiconductor layer having a film thickness of 2000 nm from mixed gas of SiH₄ and H₂, and then an n-type microcrystalline silicon semiconductor layer having a film thickness of 20 nm from mixed gas of SiH₄, H₂, and PH₃. Details of various conditions applicable to the plasma CVD method are similar to those in Table 1.

Meanwhile, YAG laser is irradiated from the microcrystalline silicon semiconductor layer 53 side. A irradiated position is laterally spaced apart by 50 μm from the patterned position of the ZnO electrode 52. In this way, the microcrystalline silicon semiconductor layer 53 is patterned into a strip shape. In this laser separation process, employed is Nd:YAG laser having an energy density of 0.7 J/cm³ and a pulse frequency of 3 kHz. Next, an Ag electrode 54 having a thickness of 200 nm is formed on the microcrystalline silicon semiconductor layer 53 by the sputtering method. The Ag electrode 54 is also formed in the region obtained by removing the microcrystalline silicon semiconductor layer 53 by patterning.

Meanwhile, the Ag electrode 54 and the microcrystalline silicon semiconductor layer 53 in portions laterally spaced apart from the patterned position of the microcrystalline silicon semiconductor layer 53 by 50 μm are irradiated by YAG laser from the light entering side, and thus are patterned into strip shapes. In this laser separation process, employed is Nd:YAG laser having an energy density of 0.7 J/cm³ and a pulse frequency of 3 kHz. In this way, in the region where the Ag electrodes are electrically separated, the microcrystalline silicon semiconductor layer 53 is removed from the surface of the ZnO electrode 12 at the side of the rear surface. Accordingly, a submodule in which the multiple photovoltaic elements are connected to each other in series is formed on the glass substrate 11.

Next, external electrodes are provided by use of ultrasonic solder and copper foil leads.

Next, EVA 55 and a PET film 56 are sequentially provided on the photovoltaic elements and are heat-treated at 150° C. for 30 minutes by using a laminating apparatus. In this way, the EVA is cross-linked and stabilized, thereby vacuum-bonding the EVA. Here, the EVA 55 is also filled into the region where the Ag electrodes are electrically separated, so that the ZnO electrode 52 contacts the EVA 55.

Lastly, the thin film solar cell module according the conventional example is completed by attaching a terminal box and connecting the external electrodes thereto.

(Reliability Evaluation)

Reliability evaluation of weather resistance is conducted in order to compare reliabilities between the thin film solar cell modules according to the examples and the thin film solar cell module according to the conventional example. To be more precise, moisture resistance test is conducted for measuring change ratios of output characteristics of the respective modules in an environment at the temperature equal to 85° C. and the humidity equal to 85%. Here, the change ratios of the output characteristics is indicated by indexation of temporal changes of outputs relative to each output at the initiation of the test defined as 1.00.

(Results)

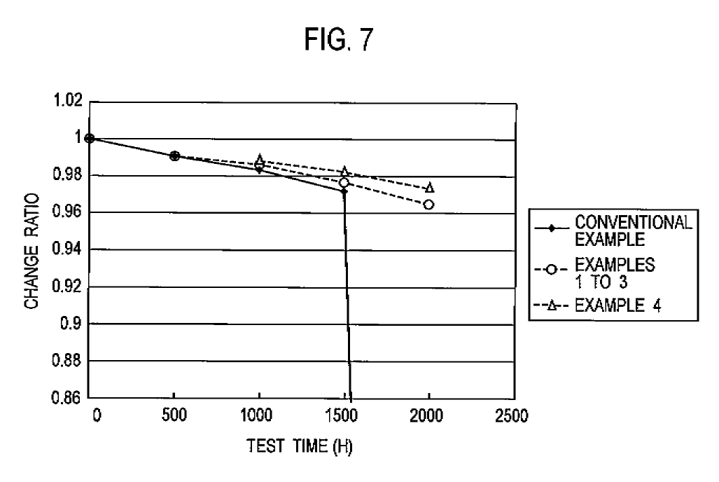

Measurement results are shown in FIG. 7. Fig. shows the change ratios of the output characteristics of the respective solar cell modules in time series.

In the thin film solar cell module according to the conventional example, the output becomes unstable after about 1000 hours from the start of the test and the output suddenly drops after about 1500 hours. Moreover, the output is lost after about 1800 hours.

In contrast, the thin film solar cell modules according to Examples 1 to 4 show values equal to or above 95% after 2000 hours from the start of the test. This result shows that the thin film solar cell modules according to Examples 1 to 4 can maintain stable and high outputs.

To check the cause of the results shown in FIG. 7, output characteristics of each photovoltaic elements in the thin film solar cell module according to the conventional example after the test are measured. As a consequence, it is confirmed that some of the photovoltaic elements show the state of not emitting voltage, i.e. the state of conduction failures. When the inside of the photovoltaic element having the conduction failure is observed with a microscope, external appearance of ZnO contacting the EVA 55 is apparently changed. Thus it is confirmed that ZnO of that portion is deteriorated by moisture.

The reason that no output is generated from the solar cell module is presumably because the moisture penetrating the EVA 55 deteriorates the ZnO electrode 52 in the region in which the Ag electrodes 54 of the photovoltaic elements adjacent to each other are electrically separated, and thereby causing conduction failures among some of the photovoltaic elements.

On the other hand, in the thin film solar cell modules according to Examples 1 and 2, the metal layer 18 covers the ZnO electrode 12 in the region where the Ag electrodes 15 of the photovoltaic elements adjacent to each other are electrically separated. Meanwhile, in the thin film solar cell modules according to Examples 3 and 4, the metal layer 18 is located inside the ZnO electrode 12 in the region where the Ag electrodes 15 of the photovoltaic elements adjacent to each other are electrically separated.

In this way, the results show that the thin film solar cell modules according the examples can maintain stable and high outputs with the presence of the metal layer 18 that prevents the ZnO electrode 12 from deteriorating even when the moisture penetrates in the EVA 16.

In addition, ZnO has not been put into practical use due to the characteristic that it is easily deteriorated by moisture, irrespective of the fact that ZnO has a significant advantage as the material of the transparent conductive film. However, from the results of this reliability evaluation, it is confirmed that ZnO can be put into practical use favorably by applying the configurations of the examples.

Note that the entire contents of Japanese Patent Application No. 2006-236146 (filed on Oct. 31, 2006) are incorporated herein by reference.

### INDUSTRIAL APPLICABILITY

As described above, according to the present invention, it is possible to provide a thin film solar cell module which is capable of maintaining a stable and high power generation even if moisture penetrates.

1. A solar cell module in which a photovoltaic layer and a sealing layer are sequentially disposed on a transparent substrate, the photovoltaic layer formed by connecting in series a plurality of photovoltaic elements each formed by sequentially stacking a first electrode, a photovoltaic conversion layer, and a second electrode,
wherein, in a region electrically separating the second electrodes of the photovoltaic elements adjacent to each other, a metal film is provided on a surface of the first electrode at a side of the sealing layer.

2. The solar cell module according to claim 1,
wherein the metal film is provided to cover a portion where the first electrode of one of the photovoltaic elements is connected to the second electrode of another photovoltaic element adjacent to the one photovoltaic element.

3. A solar cell module in which a photovoltaic layer and a sealing layer are sequentially disposed on a transparent substrate, the photovoltaic layer formed by connecting in series a plurality of photovoltaic elements each formed by sequentially stacking a first electrode, a photovoltaic conversion layer, and a second electrode,
wherein, in a region electrically separating the second electrodes of the photovoltaic elements adjacent to each other, a metal film is provided on a surface of the transparent substrate at a side of the sealing layer.

4. The solar cell module according to claim 3,
wherein the metal film is provided to extend from the surface of the transparent substrate at the side of the sealing layer so as to contact the sealing layer.

5. The solar cell module according to any of claims 1,
wherein the metal film has a high melting point equal to or above 1700° C.

6. The solar cell module according to any of claims 1,
wherein the first electrode contains ZnO.
